(19) United States
(12) Patent Application Publication
(10) Pub. No.: US 2013/0248905 A1
(43) Pub. Date: Sep. 26, 2013

(54) LED PACKAGE AND METHOD OF MANUFACTURING THE SAME

(71) Applicants: Ju-Kyung LEE, Hwaseing-si (KR); Kook-jin Oh, Ansan-si (KR); Dae-young Kim, Hwaseong-si (KR)

(72) Inventors: Ju-Kyung LEE, Hwaseing-si (KR); Kook-jin Oh, Ansan-si (KR); Dae-young Kim, Hwaseong-si (KR)

(21) Appl. No.: 13/614,977

(22) Filed: Sep. 13, 2012

(30) Foreign Application Priority Data
Mar. 22, 2012 (KR) 10-2012-0029405

(51) Int. Cl. H01L 33/52; H01L 33/50

(52) U.S. Cl. 257/98; 438/27; 438/26; 257/E33.061; 257/E33.059

(57) ABSTRACT

A light-emitting diode (LED) package and related method of manufacturing are provided. The LED package includes a resin blocking portion to prevent a transparent resin from reaching a contact terminal of the LED package during the formation of the lens for the LED package.

### CROSS-REFERENCE TO RELATED APPLICATIONS

This application claims the benefit of Korean Patent Application No. 10-2012-0029405, filed on Mar. 22, 2012, in the Korean Intellectual Property Office, the disclosure of which is incorporated herein in its entirety by reference.

### TECHNICAL FIELD

The present disclosure relates to a light-emitting diode (LED) package and a method of manufacturing the same, and more particularly, to an LED package having improved electrical connection with an external power source and a method of manufacturing the LED package.

### BACKGROUND

A light-emitting diode (LED) is a semiconductor device for converting electrical energy into light energy and is formed of a compound semiconductor that emits light with a particular wavelength according to an energy band gap. LEDs have been used in various fields such as lighting and display fields, and the like.

LEDs are used in the form of a package of a required type according to the purpose of use. In general, an LED package is configured in such a way that an LED chip is mounted on a substrate on which an electrode pattern is formed and a lens is disposed to cover the LED chip. In this case, the lens is used to control the brightness and view angle of light emitted from the LED package. In general, the lens is formed on the substrate by using a method in which a mold is disposed on the substrate, a transparent resin is injected into the mold, and then the transparent resin is hardened. Examples of the method include injection molding, compression molding, and the like.

However, when such a molding method is used, a gap is occasionally formed between the mold and the substrate, and thus, the transparent resin can leak out of the mold. When the leaking transparent resin reaches a contact terminal of the LED package and partially or entirely covers the contact terminal, it can cause a contact failure when the contact terminal contacts an external power unit.

Hence it is desirable to provide an improved light-emitting diode (LED) package and related method of manufacturing which prevent a contact failure of a contact terminal.

### SUMMARY

The teachings herein alleviate one or more of the above noted problems and provide an improved a light-emitting diode (LED) package that prevents a contact failure of a contact terminal and a method of manufacturing the same.

An exemplary method of manufacturing a light-emitting diode (LED) includes preparing a printed circuit board (PCB) including a mounting portion on which an LED chip is mounted, a resin blocking portion formed outside an edge of the mounting portion, and a contact terminal disposed outside of an edge of the resin blocking portion and electrically connected to the LED chip. The method includes preparing a mold including a convex portion defining a cavity in which a transparent resin is filled, and a contact portion constituting an edge of the convex portion. The mold is mounted on the PCB such that the contact portion is disposed inside the resin blocking portion. The transparent resin is filled in the cavity. The transparent resin is blocked from leaking past the resin blocking portion in the direction of the contact terminal.

In certain examples, the resin blocking portion protrudes from an upper surface of the PCB or is concaved on the upper surface of the PCB.

The resin blocking portion may be continually formed along an edge of the contact portion.

The resin blocking portion may be formed to have a protrusion height that is less than or equal to a protrusion height of the contact portion.

The resin blocking portion may be formed by using any one of a photolithography method and a screen printing method.

The PCB may be configured such that a phosphor is disposed on the LED chip.

According to another aspect of the present teachings, an LED package is provided. The LED package includes a PCB and an LED chip mounted on the PCB. A contact terminal is electrically connected to the LED chip. A lens is disposed on the LED chip to cover the LED chip. A resin blocking portion is disposed on an upper surface of the PCB between an edge of the lens and the contact terminal.

The resin blocking portion may be spaced apart from an edge of the lens.

The resin blocking portion may be continually formed along an edge of the contact portion.

The resin blocking portion may protrude from an upper surface of the PCB or may be concaved on the upper surface of the PCB.

A phosphor may be disposed on the LED chip and the lens may cover the phosphor.

The lens may have a hemispherical shape.

In yet another example, a method of method of manufacturing a light-emitting diode (LED) is provided. The method includes mounting an LED chip on a mounting portion of a printed circuit board (PCB). A contact terminal electrically connected to the LED chip is provided. A resin blocking portion is formed between the mounting portion and the contact terminal. A mold is provided and includes a cavity for containing a transparent resin and a contact portion for contacting an upper surface of the PCB. The mold is mounted on the upper surface of the PCB such that the contact portion is disposed between the resin blocking portion and the LED chip. The transparent resin is filled in the cavity, such that the transparent resin cavity does not reach the contact terminal.

According to the above-described aspects of present teachings, the LED package and the method of manufacturing the same can restrict movement of a leaking transparent resin due to a modified structure of an upper surface of a PCB, thereby preventing a contact failure due to the transparent resin.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 is a cross-sectional view of an exemplary light-emitting diode (LED) package;

FIG. 2 is a plan view of the LED package of FIG. 1;

FIG. 3 is a cross-sectional view of another exemplary LED package;

FIGS. 4A through 4D are diagram examples for explaining a method of manufacturing an LED package;

FIGS. 5A through 5D are diagram examples for explaining another method of manufacturing an LED package;

FIG. 6 is a schematic plan view of an LED package according to Comparative Example 1; and

FIG. 7 is a schematic plan view of an LED package according to Example 1.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings. In the drawings, the thicknesses of layers and regions may be exaggerated for clarity.

FIG. 1 is a cross-sectional view of an LED package 10 FIG. 1 illustrates a printed circuit board (PCB) 100, an LED chip 110, a contact terminal 130, a lens 150, and a resin blocking portion 170.

The LED chip 110 is mounted on the PCB 100. According to this example, the LED package 10 is a chip-on-board (COB) type LED package 10 in which the LED chip 10 is mounted directly on the PCB 100, as shown in FIG. 1. Since the COB type LED package 10 is mounted directly on the PCB 100, it is not required to perform a conventional method in which the LED chip 110 is mounted on a lead frame and then a separate process of connecting the lead frame to the PCB 100 is performed. That is, according to this example, by using the COB type LED package 10, the amount of time and cost required for connection with the PCB 100 after completion of a package may be reduced.

In this case, although not illustrated in FIG. 1, the LED chip 110 may include an n-type semiconductor layer, an active layer, and a p-type semiconductor layer. When a voltage is applied to the LED chip 110, electrons of the n-type semiconductor layer and the holes of the p-type semiconductor layer move to the active layer and are recombined with each other. Light is emitted from the active layer due to an energy difference formed when the electrons and the holes are recombined with each other. Although a single LED chip 110 is illustrated in FIG. 1, a plurality of LED chips may instead be used. The plurality of LED chips may be arranged in various forms. Example of the arrangement may include a radial form or a linear form.

The contact terminal 130 electrically contacts the LED chip 110. The contact terminal 130 is spaced apart from the LED chip 110 on the PCB 100 and is exposed to the outside. Electrodes of the LED chip 110, for example, an anode and a cathode may be connected to the contact terminal 130. However, a connection structure of the contact terminal 130 and the LED chip 110 is not limited to the structure shown in FIG. 1. That is, various connection methods may be used according to the structure of the LED chip 110. The contact terminal 130 that is exposed to the outside may be disposed outside an edge of the resin blocking portion 170 that will be described below.

In the example of FIG. 1, the lens 150 is disposed on the LED chip 110 and is used to control the brightness and view angle of light emitted from the LED chip 110. The lens 150 may include a transparent resin, for example, silicon, epoxy, or a combination thereof.

The lens 150 may be formed in various forms in consideration of the brightness, view angle, or the like of light. For example, the lens 150 may have a hemispherical shape, as shown in FIG. 1.

The resin blocking portion 170 in FIG. 1 is disposed between an edge of the lens 150 and the contact terminal 130. In addition, the resin blocking portion 170 is formed on an upper surface of the PCB 100.

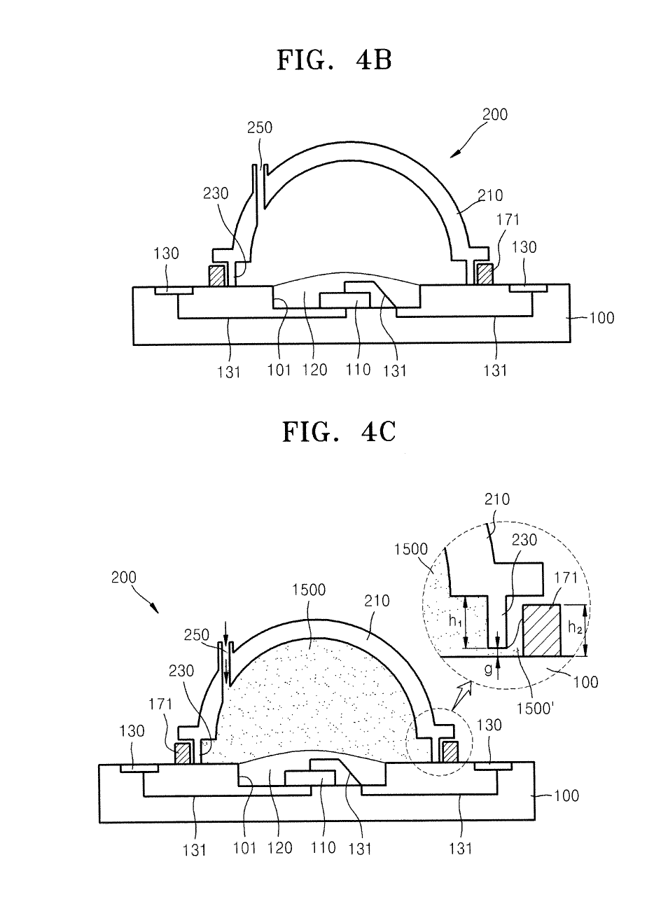

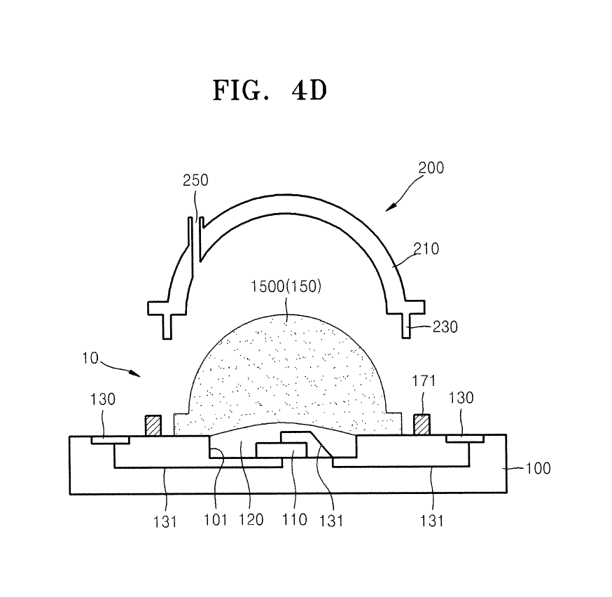

For example, the resin blocking portion 170 may protrude from the upper surface of the PCB 100, as shown in FIG. 1. A protruding resin blocking portion 171 may be spaced apart from the edge of the lens 150. The lens 150 is formed of a transparent resin 1500 (see FIG. 4C) that is fluid before hardening during the formation of the lens 150. A portion 1500′ (hereinafter, referred to as the leaking transparent resin 1500′) of the transparent resin 1500 may leak out of a mold 200 (see FIG. 4C). In this case, the protruding resin blocking portion 171 serves as a dam or barrier for preventing movement of the leaking transparent resin 1500′, thereby preventing the transparent resin 1500 from reaching the contact terminal 130. Thus, a contact failure of the contact terminal 130, which may be caused when the transparent resin 1500 reaches the contact terminal 130, may be prevented.

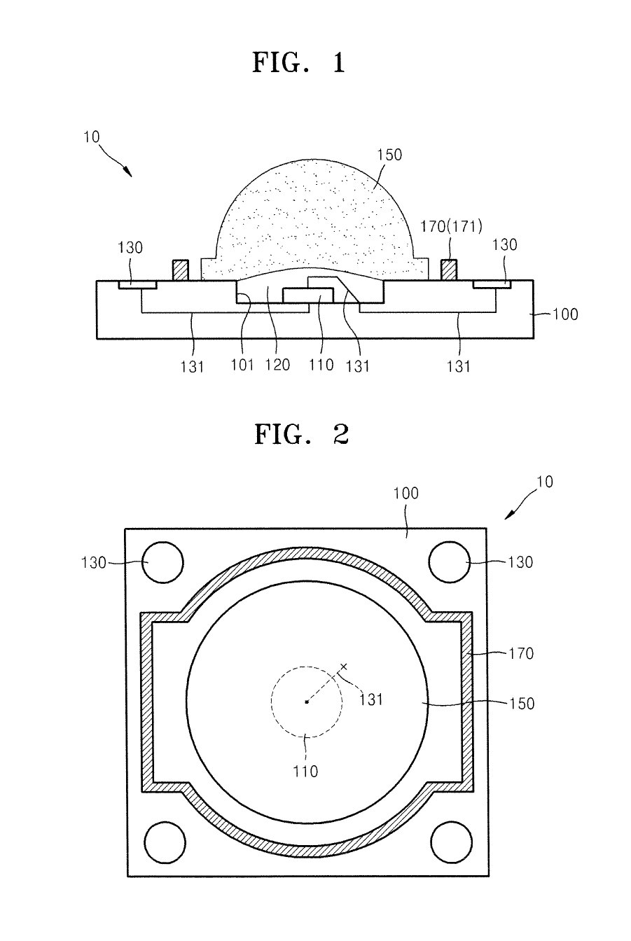

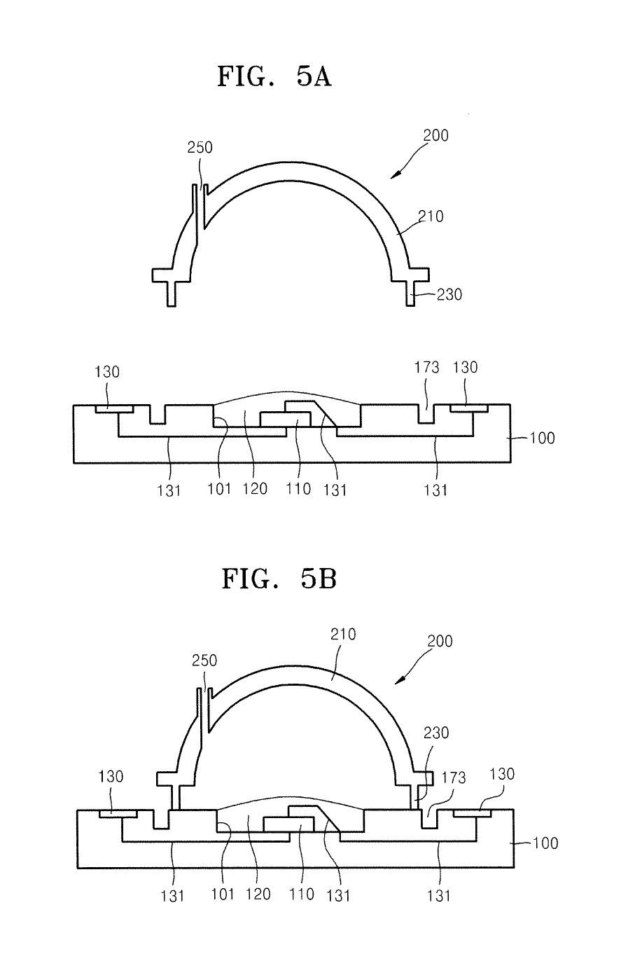

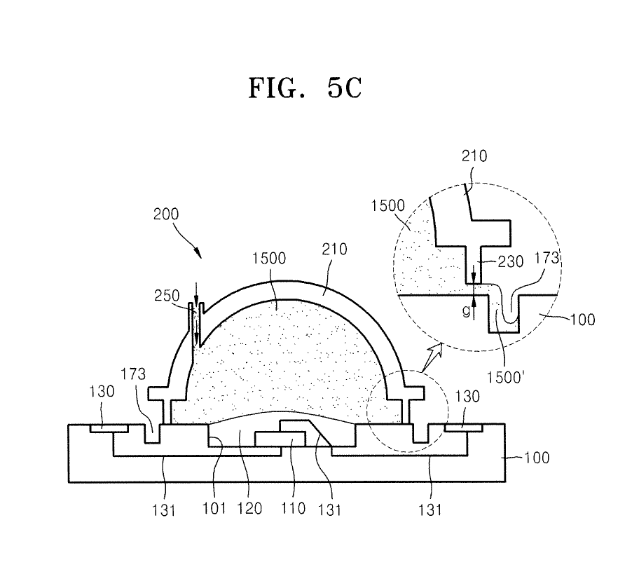

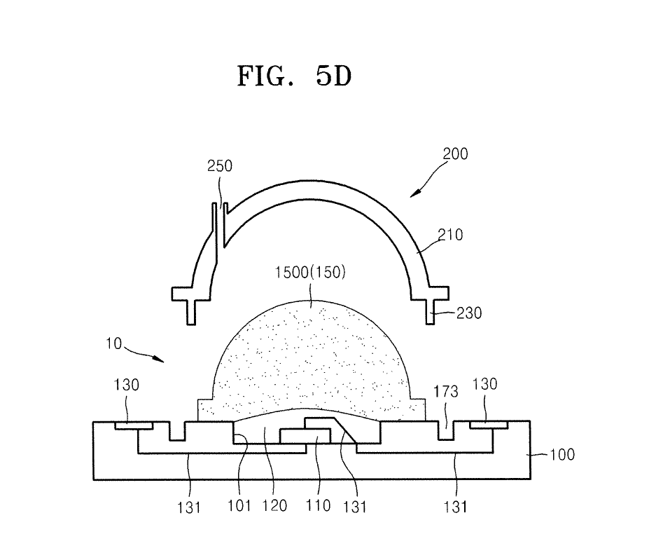

FIG. 2 is a plan view of the LED package 10 of FIG. 1, according to another example The resin blocking portion 170 has a continuous shape by being continually formed along the edge of the lens 150. In other words, the resin blocking portion 170 has a shape so as to surround an external circumference of a region where the lens 150 contacts the PCB 100. Thus, movement of the leaking transparent resin 1500′ may be effectively prevented regardless of a position of a gap ‘g’ (see FIGS. 4C and 5C) that is formed between the mold 200 and the PCB 100 during the formation of the lens 150. In addition, the resin blocking portion 170 is spaced apart from the lens 150 by a predetermined interval. A region of the upper surface of the PCB 100, on which the resin blocking portion 170 is spaced apart from the lens 150, may be used for connection with the mold 200 during the formation of the lens 150.

Referring back to FIG. 1, a phosphor 120 may be disposed on the LED chip 110. The phosphor 120 may be formed by mixing a phosphor material with a resin and may include a phosphor material for converting a wavelength into any one of yellow, red, and green wavelengths. In particular, when the LED chip 110 generates a blue wavelength, a yellow light-emitting phosphor material is used as the phosphor 120, thereby converting light passing through the lens 150 into white light.

The phosphor 120 may be disposed on a mounting portion 101 on which the LED chip 110 is mounted. The mounting portion 101 may be formed in the form of a groove that is concaved on the PCB 100, as shown in FIG. 1, but is not limited thereto. That is, the mounting portion 101 may be embodied in various forms.

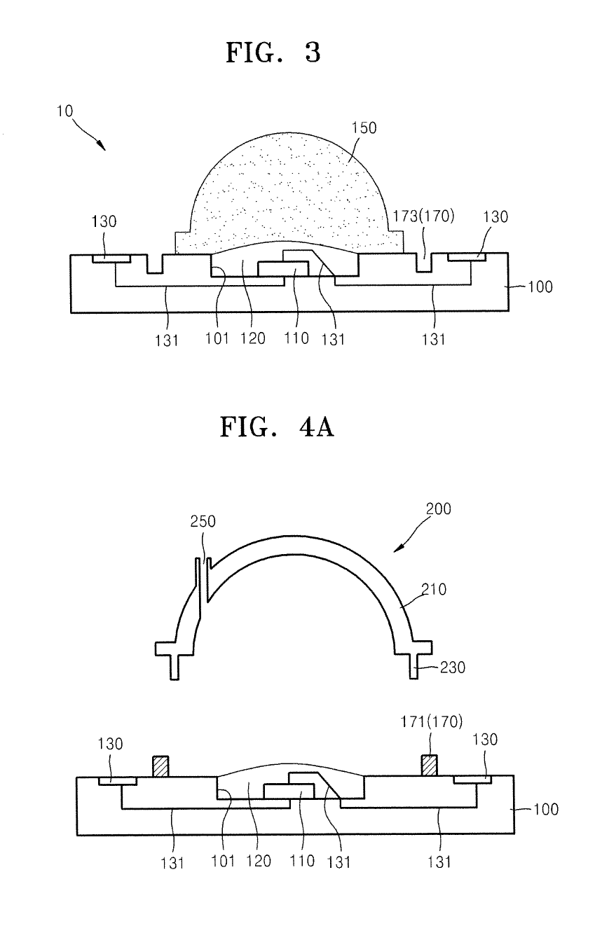

FIG. 3 is a cross-sectional view of an LED package 10 according to another example. According to this example, the LED package 10 has a substantially similar structure as shown in FIG. 1, except that the resin blocking portion 170 is concaved in the PCB 100. The LED package 10 may include the PCB 100, the LED chip 110, the contact terminal 130, the lens 150, and a concaved resin blocking portion 173.

The concaved resin blocking portion 173 shown in FIG. 3 is concaved downwards on an edge of the upper surface of the PCB 100. The concaved resin blocking portion 173 may be disposed outside an edge of the lens 150 similar to the protruding resin blocking portion 171 of FIG. 1. In addition, the concaved resin blocking portion 173 may be disposed inside the contact terminal 130 with respect to the lens 150. The concaved resin blocking portion 173 may accommodate the leaking transparent resin 1500′ (see FIG. 5C) that leaks out of the mold 200 (see FIG. 4C) during the formation of the lens 150, thereby preventing the leaking transparent resin 1500′ from reaching the contact terminal 130. In detail, when the transparent resin 1500 leaks out of the mold 200 during the formation of the lens 150, the leaking transparent resin 1500′ is accommodated in the concaved resin blocking portion 173 before reaching the contact terminal 130. As long as the amount of the leaking transparent resin 1500′ that is accommodated in the concaved resin blocking portion 173 does not exceed the volume of the concaved resin blocking portion 173, the leaking transparent resin 1500′ may not reach the contact terminal 130. Thus, a contact failure of the contact terminal 130, which may be caused when the leaking transparent resin 1500′ reaches the contact terminal 130, may be prevented.

In addition, the concaved resin blocking portion 173 in FIG. 3 is spaced apart from the lens 150 by a predetermined interval, like the protruding resin blocking portion 171 according to the above-described example is continually formed along the edge of the lens 150.

As a depth of the concaved resin blocking portion 173 is increased, a volume of the concaved resin blocking portion 173, for accommodating the leaking transparent resin 1500′ that leaks out of the mold 200, is increased. In this case, the depth of the concaved resin blocking portion 173 may be limited such that the concaved resin blocking portion 173 may not contact an electric conductor 131 for connecting the contact terminal 130 and the LED chip 110 to each other.

FIGS. 4A through 4D are exemplary diagrams for explaining a method of manufacturing an LED package 10 The method of manufacturing the LED package 10 may include preparing the PCB 100, preparing the mold 200, mounting the mold 200 on the PCB 100, filling with the transparent resin 1500, and blocking the leaking transparent resin 1500′. Each process step will be described below in more detail.

FIG. 4A shows a case where the PCB 100 and the mold 200 are prepared. The PCB 100 includes the mounting portion 101 on which the LED chip 110 is mounted, the resin blocking portion 170 formed outside the mounting portion 101, and the contact terminal 130 that is disposed outside the resin blocking portion 170 and is electrically connected to the LED chip 110. The LED chip 110 emits light when an external voltage is applied to the contact terminal 130.

For example, the resin blocking portion 170 protrudes from the upper surface of the PCB 100, as shown in FIG. 4A. The contact terminal 130 is disposed outside the edge of the protruding resin blocking portion 171.

In addition, the phosphor 120 may be coated on the LED chip 110 mounted on the PCB 100. The phosphor 120 may be formed by mixing a phosphor material with a resin and may include a phosphor material for converting a wavelength into any one of yellow, red, and green wavelengths. In particular, when the LED chip 110 generates a blue wavelength, a yellow light-emitting phosphor material is used as the phosphor 120, thereby converting light passing through the lens 150 into white light.

The mold 200 is a member for forming the lens 150 on the LED chip 110. The mold 200 includes a convex portion 210 of which an inner circumference surface for fixing a shape of the lens 150 is convex and a contact portion 230 constituting an edge of the convex portion 210.

FIG. 4B shows an example where the PCB 100 and the mold 200 contact each other. The mold 200 is mounted on the PCB 100 such that the contact portion 230 is disposed inside the protruding resin blocking portion 171. The mold 200 that contacts the PCB 100 forms a cavity between the convex portion 210 and the PCB 100. The cavity is sealed by the contact portion 230 that contacts the PCB 100. In order to increase a sealing degree using the contact portion 230, a shape of an end portion of the contact portion 230 may be changed. For example, although not illustrated, the end portion of the contact portion 230 is processed to have a sharp shape, thereby reducing a contact area in order to increase a pressing force against the PCB 100.

FIG. 4C shows an example where the transparent resin 1500 is filled in the mold 200. FIG. 4D shows a case where the mold 200 is separated from the PCB 100 after the transparent resin 1500 is hardened. Referring to FIG. 4C, the transparent resin 1500 is injected into the convex portion 210, that is, the cavity through a transparent resin injection port 250 formed in the mold 200. When the transparent resin 1500 is completely filled in the convex portion 210, the transparent resin 1500, that is, the lens 150 may have a desired shape. In this state, when the transparent resin 1500 is hardened in a high-temperature environment, the lens 150 may be formed on the LED chip 110 to have a desired shape. Lastly, as shown in FIG. 4D, when the mold 200 is separated from the PCB 100, the LED package 10 is completely manufactured. In this case, a single transparent resin injection port 250 is used, but if necessary, a plurality of transparent resin injection ports may be used.

As described above, when the transparent resin 1500 is injected, the contact portion 230 seals a space between the convex portion 210 and the PCB 100, thereby preventing the transparent resin 1500 from leaking out of the mold 200.

However, as shown in FIG. 4C, the gap ‘g’ may be formed between the contact portion 230 and the PCB 100 due to various reasons such as manufacturing environments, a planarization difference between regions where the contact portion 230 and the PCB 100 overlap with each other, or the like. The protruding resin blocking portion 171 is formed outside an edge of the contact portion 230 and prevents the leaking transparent resin 1500′ from reaching the contact terminal 130 through the gap ‘g’.

That is, as described above, during the manufacture of the LED package 10, the transparent resin 1500 injected into the mold 200 may be primarily blocked by the contact portion 230 formed on the mold 200 and may be secondarily blocked by the protruding resin blocking portion 171 of the PCB 100, thereby preventing the transparent resin 1500 from reaching the contact terminal 130.

The contact portion 230 of the mold 200 may protrude from the convex portion 210 toward the PCB 100. An end portion of the contact portion 230 may directly contact the PCB 100. The protruding resin blocking portion 171 may protrude to have a protrusion height h₂ that is smaller than or equal to a protrusion height h₁ of the contact portion 230 in order to prevent interference with the mold 200.

The protruding resin blocking portion 171 is spaced apart from the contact portion 230 in a horizontal direction and is continually formed along an external circumference of the contact portion 230. Thus, movement of the leaking transparent resin 1500′ may be effectively prevented regardless of a position of the gap ‘g’ that is formed between the contact portion 230 and the PCB 100 during the formation of the lens 150.

The protruding resin blocking portion 171 may be formed by using various methods. For example, the protruding resin blocking portion 171 may be formed by using a photolithography method, a screen printing method, or the like.

FIGS. 5A through 5D are exemplary diagrams for explaining another method of manufacturing an LED package 10 The LED package 10 has a substantially similar structure as in the above-described example for FIGS. 4A-4D. However, the concaved resin blocking portion 173 is formed on the PCB 100 instead of the protruding resin blocking portion 171.

The concaved resin blocking portion 173 may be disposed outside an edge of the contact portion 230 like the protruding resin blocking portion 171 according to the above-described example. The concaved resin blocking portion 173 prevents the leaking transparent resin 1500′ from reaching the contact terminal 130 through the gap ‘g’. In detail, during the formation of the lens 150, when the transparent resin 1500 leaks out of the mold 200 through the gap ‘g’, the leaking transparent resin 1500′ is accommodated in the concaved resin blocking portion 173 before reaching the contact terminal 130, as shown in FIG. 5C. As long as the amount of the leaking transparent resin 1500′ that is accommodated in the concaved resin blocking portion 173 does not exceed the volume of the concaved resin blocking portion 173, the transparent resin 1500 may not reach the contact terminal 130. Thus, a contact failure of the contact terminal 130, which may be caused when the transparent resin 1500 reaches the contact terminal 130, may be prevented.

That is, during the manufacturing of the LED package 10, the transparent resin 1500 injected into the mold 200 may be primarily blocked by the contact portion 230 formed on the mold 200 and may be secondarily blocked by the concaved resin blocking portion 173, thereby preventing the transparent resin 1500 from reaching the contact terminal 130.

The concaved resin blocking portion 173 is spaced apart from the contact portion 230 in a horizontal direction and is continually formed along an external circumference of the contact portion 230. Thus, movement of the leaking transparent resin 1500′ may be effectively prevented regardless of a position of the gap ‘g’ that is formed between the contact portion 230 and the PCB 100 during the formation of the lens 150.

The concaved resin blocking portion 173 may be formed by using various methods. For example, the concaved resin blocking portion 173 may be formed by using a photolithography method.

### Example 1

In this example of manufacturing the LED package 10, the PCB 100 and the mold 200 are prepared. The LED chip 110 is mounted on the mounting portion 101 of the PCB 100. The contact terminal 130 is disposed on an edge portion of the PCB 100. The mold 200 includes the convex portion 210 having a convex shape as an inner shape and the contact portion 230 that contacts the PCB 100.

The PCB 100 and the mold 200 contact each other and then silicon (Si) as the transparent resin 1500 is injected into the convex portion 210 through the transparent resin injection port 250. After the silicon is complexly filled in the convex portion 210, the silicon is hardened at a high temperature to form the lens 150 on the PCB 100.

### Comparative Example 1

As with a conventional method, a PCB has an upper surface on which no step difference between the contact portion 230 of the mold 200 and the contact terminal 130 is formed.

### Example 1

The PCB 100 has an upper surface on which a protrusion between the contact portion 230 of the mold 200 and the contact terminal 130 is formed to have a height of about 30 μm and the protruding resin blocking portion 171 is formed of UV ink. The protruding resin blocking portion 171 is formed by using a photolithography method.

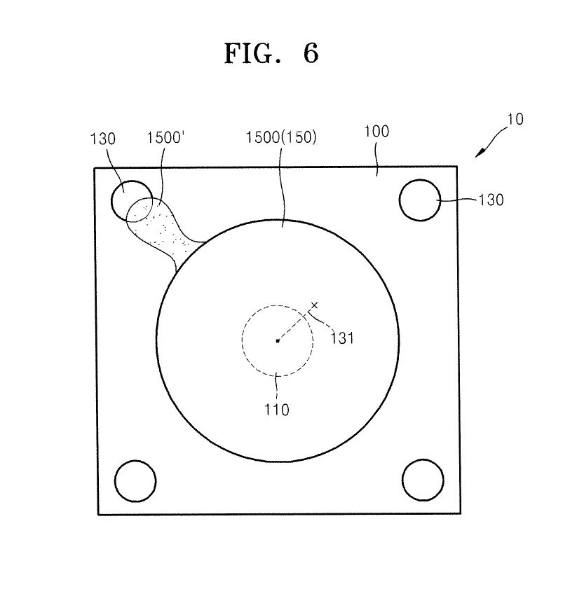

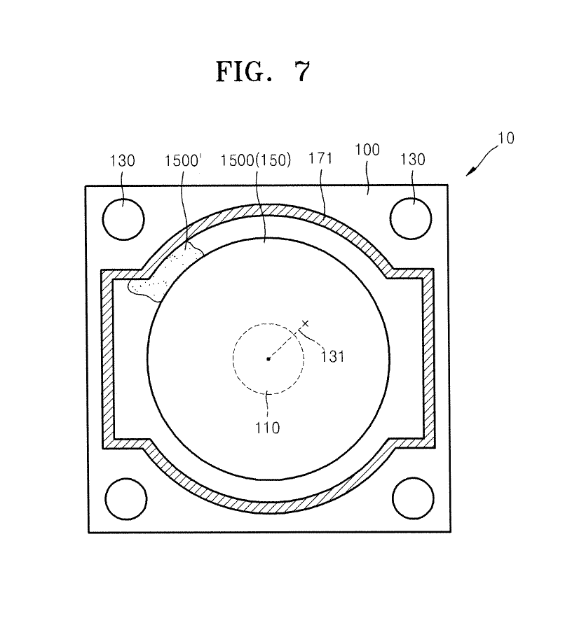

FIG. 6 is a schematic plan view of the LED package 10 according to Comparative Example 1. FIG. 7 is a schematic plan view of the LED package 10 according to Example 1.

In the LED package 10 according to Comparative Example 1, silicon 1500′ is shown leaking through the gap ‘g’ (see FIG. 4C) formed between the mold 200 and the PCB 100 and reaching the contact terminal and thus contaminating the contact terminal 130, as shown in FIG. 6.

However, in the LED package 10 according to Example 1, although the silicon 1500′ partially leaks out of the mold 200, movement of the silicon 1500′ is restricted by the protruding resin blocking portion 171. Thus, it is confirmed that the silicon 1500′ does not reach the contact terminal 130. That is, the silicon 1500′ that leaks through the gap ‘g’ in this Example 1 does not contaminate the contact terminal 130. Example 1 was repeated about 180 times by using an injection molding method and repeated about 252 times by using a compression molding method. However, it is confirmed with each repeated example, that the silicon 1500′ that leaks out of the mold 200 does not reach the contact terminal 130 at all.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A method of manufacturing a light-emitting diode (LED) package, the method comprising steps of:
preparing a printed circuit board (PCB) including:
a mounting portion on which an LED chip is mounted,
a resin blocking portion formed outside an edge of the mounting portion, and
a contact terminal disposed outside of an edge of the resin blocking portion and electrically connected to the LED chip;
preparing a mold including:
a convex portion defining a cavity in which a transparent resin is filled, and
a contact portion constituting an edge of the convex portion;
mounting the mold on the PCB such that the contact portion is disposed inside the resin blocking portion; and
filling the transparent resin in the cavity,
wherein the transparent resin is blocked from leaking past the resin blocking portion in the direction of the contact terminal.

2. The method of claim 1, wherein the resin blocking portion protrudes from an upper surface of the PCB.

3. The method of claim 1, wherein the resin blocking portion is concaved on the upper surface of the PCB.

4. The method of claim 1, further comprising the step of continually forming the resin blocking portion along an edge of the contact portion.

5. The method of claim 2, further comprising the step of forming the resin blocking portion to have a protrusion height that is less than or equal to a protrusion height of the contact portion.

6. The method of claim 1, further comprising the step of forming the resin blocking portion by a photolithography method or a screen printing method.

7. The method of claim 1, further comprising the step of disposing phosphor on the LED chip.

8. An LED package comprising:
a printed circuit board (PCB);
an LED chip mounted on the PCB;
a contact terminal electrically connected to the LED chip;
a lens disposed on and covering the LED chip; and
a resin blocking portion disposed on an upper surface of the PCB between an edge of the lens and the contact terminal.

9. The LED package of claim 8, wherein the resin blocking portion is spaced apart from an edge of the lens.

10. The LED package of claim 8, wherein the resin blocking portion is continually formed along an edge of the contact portion.

11. The LED package of claim 8, wherein the resin blocking portion protrudes from an upper surface of the PCB.

12. The LED package of claim 8, wherein the resin blocking portion is concaved on the upper surface of the PCB.

13. The LED package of claim 8, wherein a phosphor is disposed on the LED chip and the lens covers the phosphor.

14. The LED package of claim 8, wherein the lens has a hemispherical shape.

15. A method of manufacturing a light-emitting diode (LED) package, the method comprising steps of:
mounting an LED chip on a mounting portion of a printed circuit board (PCB);
providing a contact terminal electrically connected to the LED chip;
forming a resin blocking portion between the mounting portion and the contact terminal;
providing a mold including a cavity for containing a transparent resin and a contact portion for contacting an upper surface of the PCB;
mounting the mold on the upper surface of the PCB such that the contact portion is disposed between the resin blocking portion and the LED chip; and
filling the transparent resin in the cavity, such that the transparent resin cavity does not reach the contact terminal.

16. The method of claim 15, wherein the resin blocking portion protrudes from the upper surface of the PCB.

17. The method of claim 15, wherein the resin blocking portion is concaved on the upper surface of the PCB.

18. The method of claim 15, further comprising the step of forming the resin blocking portion continually along an edge of the contact portion.

19. The method of claim 16, further comprising the step of forming the resin blocking portion to have a protrusion height that is less than or equal to a protrusion height of the contact portion.

20. The method of claim 15, further comprising the step of forming the resin blocking portion by a photolithography method or a screen printing method.
